(19) United States
(12) Patent Application Publication
(10) Pub. No.: US 2025/0374633 A1
(43) Pub. Date: Dec. 4, 2025

(54) STRUCTURE AND FORMATION METHOD OF SEMICONDUCTOR DEVICE WITH INNER SPACER

(71) Applicant: Taiwan Semiconductor Manufacturing Co., Ltd., Hsinchu (TW)

(72) Inventors: Wen-Kai Lin, Hsinchu (TW); Po-Jen Cheng, Taoyuan City (TW); Che-Hao Chang, Hsinchu (TW); Tai-Chun Huang, Hsinchu (TW); Tze-Liang Lee, Hsinchu (TW)

(21) Appl. No.: 18/826,347

(22) Filed: Sep. 6, 2024

Related U.S. Application Data
(60) Provisional application No. 63/655,161, filed on Jun. 3, 2024.

(51) Int. Cl. H01L 29/66; H01L 21/02; H01L 29/06; H01L 29/417; H01L 29/423; H01L 29/775; H01L 29/786

(52) U.S. Cl. CPC H10D 64/021; H01L 21/02332; H01L 21/0234; H10D 62/116; H10D 64/015; H10D 64/258; H10D 30/014; H10D 30/43; H10D 30/6735; H10D 30/6757; H10D 62/121

(57) ABSTRACT

A method for forming a semiconductor device structure is provided. The method includes forming multiple sacrificial layers and multiple semiconductor layers laid out in an alternating manner. The method also includes partially removing the semiconductor layers and the sacrificial layers to expose side edges of the semiconductor layers and the sacrificial layers and partially removing the sacrificial layers from their side edges to form multiple second recesses. The method further includes introducing modifying elements to transform surface portions of the sacrificial layers and the semiconductor layers into a modified layer. The modifying elements includes nitrogen, carbon, boron, or a combination thereof. In addition, the method includes forming an inner spacer layer over the modified layer and removing the inner spacer layer and the modified layer outside of the second recesses. Remaining portions of the inner spacer layer and the modified layer form inner spacers and modified elements, respectively.

### PRIORITY CLAIM AND CROSS-REFERENCE

This application claims the benefit of U.S. Provisional Application No. 63/655,161, filed on Jun. 3, 2024, the entirety of which is incorporated by reference herein.

### BACKGROUND

The semiconductor integrated circuit (IC) industry has experienced rapid growth. Technological advances in IC materials and design have produced generations of ICs. Each generation has smaller and more complex circuits than the previous generation. However, these advances have increased the complexity of processing and manufacturing ICs.

In the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs.

However, since feature sizes continue to decrease, fabrication processes continue to become more difficult to perform. Therefore, it is a challenge to form reliable semiconductor devices at smaller and smaller sizes.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, the dimensions of the various features may be arbitrarily increased or reduced for clarity of discussion.

FIGS. 1A-1J are cross-sectional views of various stages of a process for forming a portion of a semiconductor device structure, in accordance with some embodiments.

FIG. 1A-1 is a top view of an intermediate stage of a process for forming a portion of a semiconductor device structure, in accordance with some embodiments.

FIG. 1A-2 is a cross-sectional view of an intermediate stage of a process for forming a portion of a semiconductor device structure, in accordance with some embodiments.

FIG. 1A-3 is a cross-sectional view of an intermediate stage of a process for forming a portion of a semiconductor device structure, in accordance with some embodiments.

FIG. 1J-1 is a top view of an intermediate stage of a process for forming a portion of a semiconductor device structure, in accordance with some embodiments.

FIG. 1J-2 is a cross-sectional view of an intermediate stage of a process for forming a portion of a semiconductor device structure, in accordance with some embodiments.

FIG. 1J-3 is a cross-sectional view of an intermediate stage of a process for forming a portion of a semiconductor device structure, in accordance with some embodiments.

FIGS. 2A-2J are cross-sectional views of various stages of a process for forming a portion of a semiconductor device structure, in accordance with some embodiments.

FIG. 2J-1 is a top view of an intermediate stage of a process for forming a portion of a semiconductor device structure, in accordance with some embodiments.

FIG. 2J-2 is a cross-sectional view of an intermediate stage of a process for forming a portion of a semiconductor device structure, in accordance with some embodiments.

FIG. 2J-3 is a cross-sectional view of an intermediate stage of a process for forming a portion of a semiconductor device structure, in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Furthermore, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “substantially” in the description, such as in “substantially flat” or in “substantially coplanar”, etc., will be understood by the person skilled in the art. In some embodiments the adjective substantially may be removed. Where applicable, the term “substantially” may also include embodiments with “entirely”, “completely”, “all”, etc. The term “substantially” may be varied in different technologies and be in the deviation range understood by the skilled in the art. For example, the term “substantially” may also relate to 90% of what is specified or higher, such as 95% of what is specified or higher, especially 99% of what is specified or higher, including 100% of what is specified, though the present invention is not limited thereto. Furthermore, terms such as “substantially parallel” or “substantially perpendicular” may be interpreted as not to exclude insignificant deviation from the specified arrangement and may include for example deviations of up to 10°. The word “substantially” does not exclude “completely” e.g. a composition which is “substantially free” from Y may be completely free from Y.

The term “about” may be varied in different technologies and be in the deviation range understood by the skilled in the art. The term “about” in conjunction with a specific distance or size is to be interpreted so as not to exclude insignificant deviation from the specified distance or size. For example, the term “about” may include deviations of up to 10% of what is specified, though the present invention is not limited thereto. The term “about” in relation to a numerical value x may mean x ±5 or 10% of what is specified, though the present invention is not limited thereto.

Embodiments of the disclosure may relate to FinFET structure having fins. The fins may be patterned using any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins. However, the fins may be formed using one or more other applicable processes.

Embodiments of the disclosure may relate to the gate all around (GAA) transistor structures. The GAA structure may be patterned using any suitable method. For example, the structures may be patterned using one or more photolithography processes, including double-patterning or multi-patterning processes. In some embodiments, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Some embodiments of the disclosure are described. Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

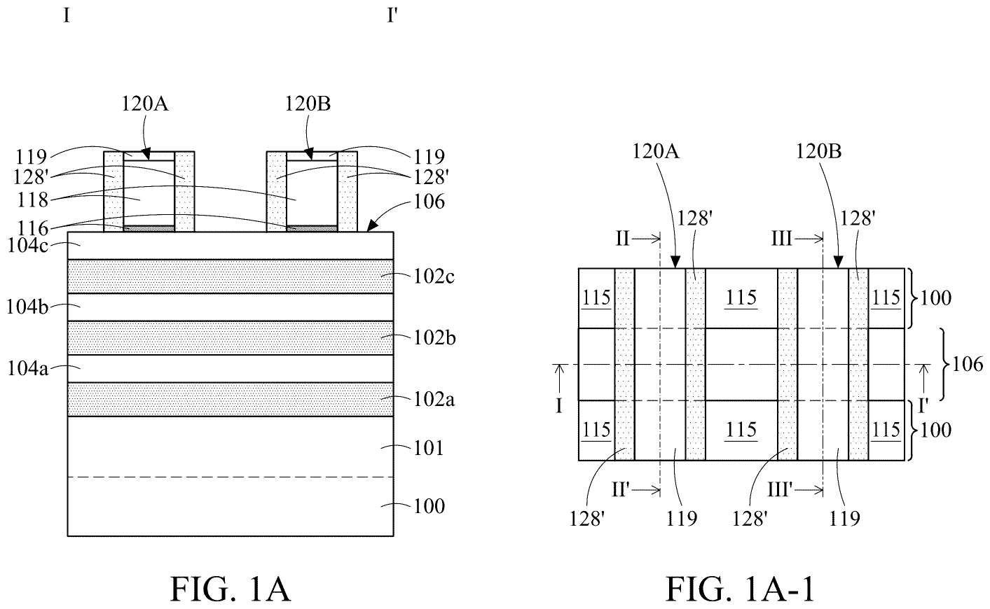

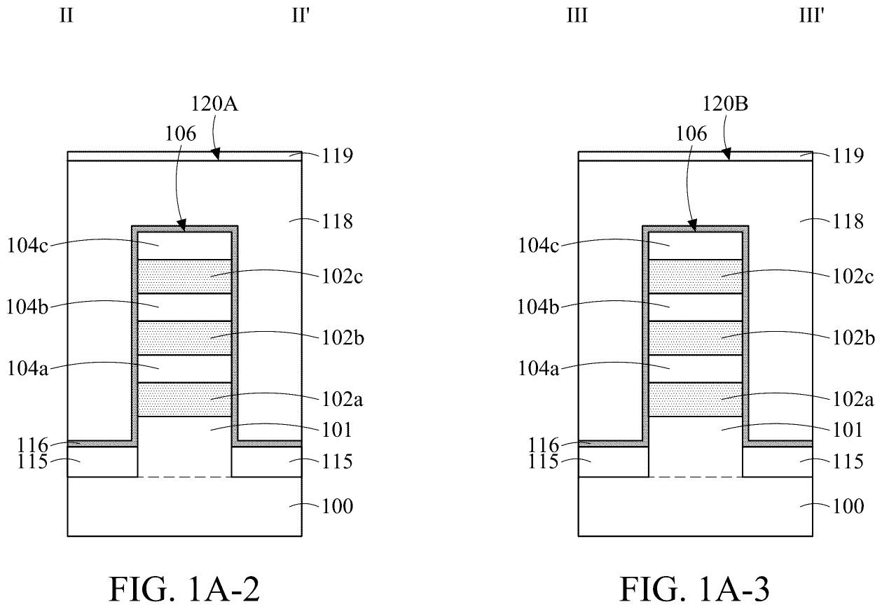

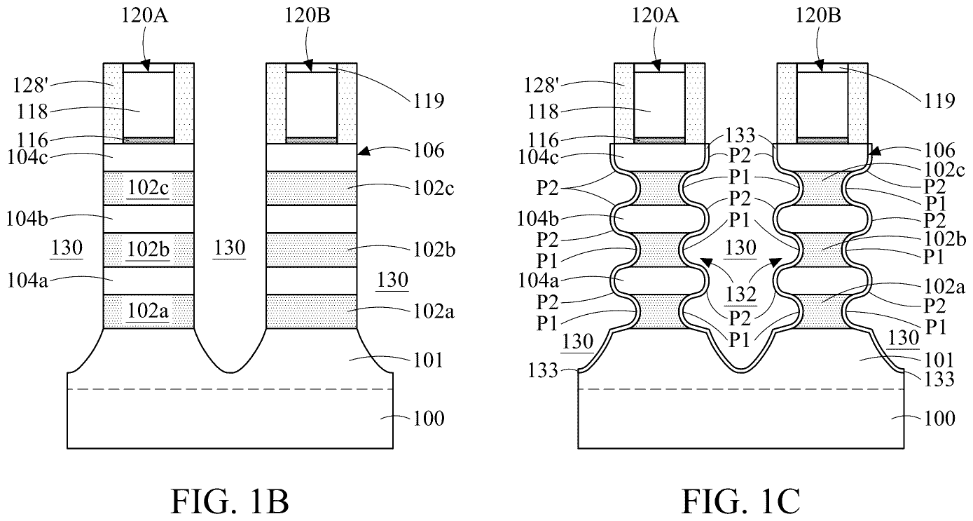

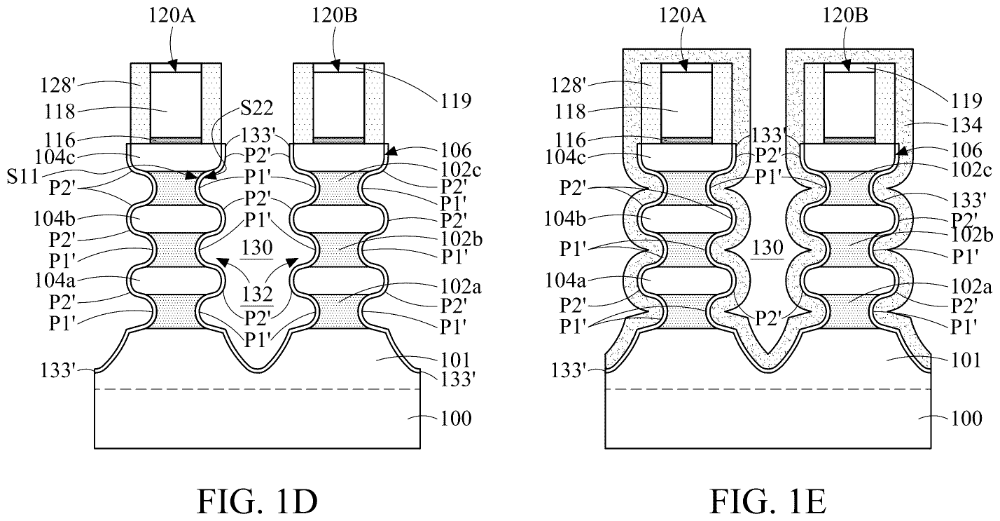

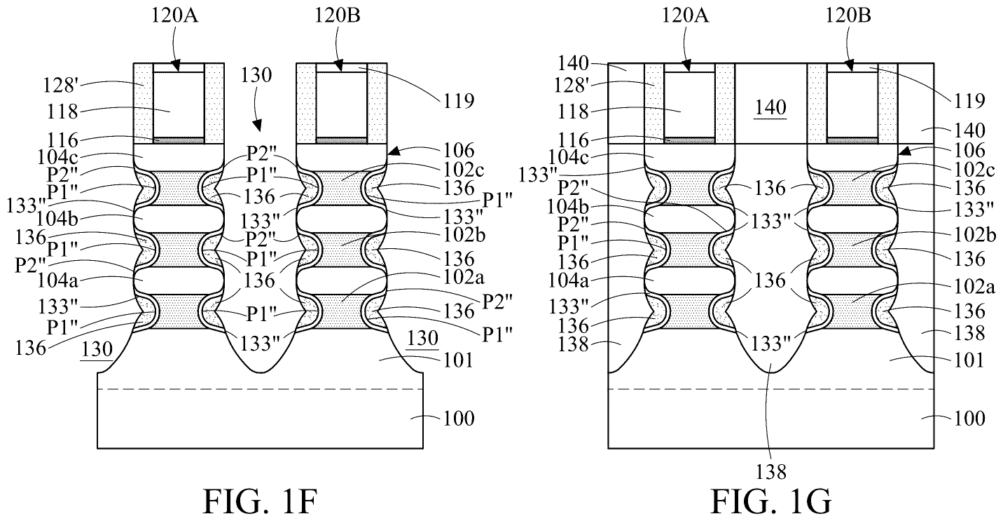

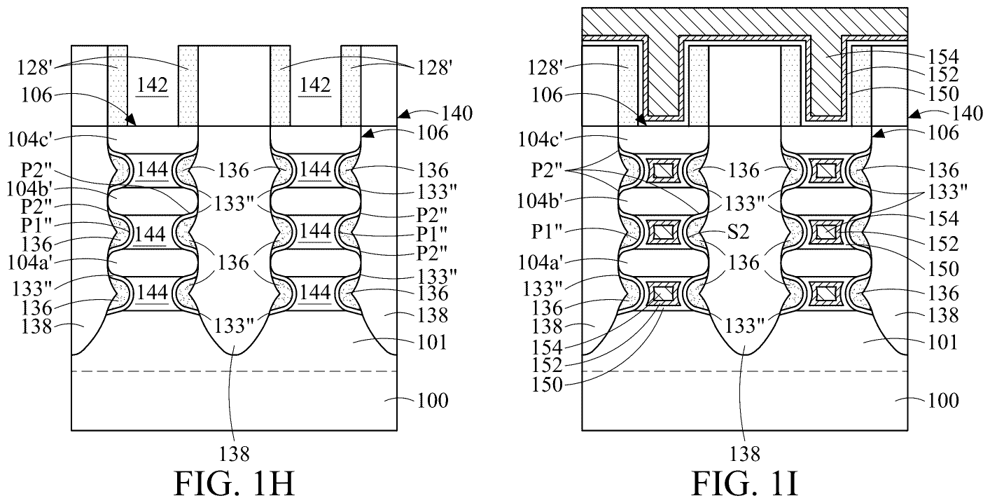

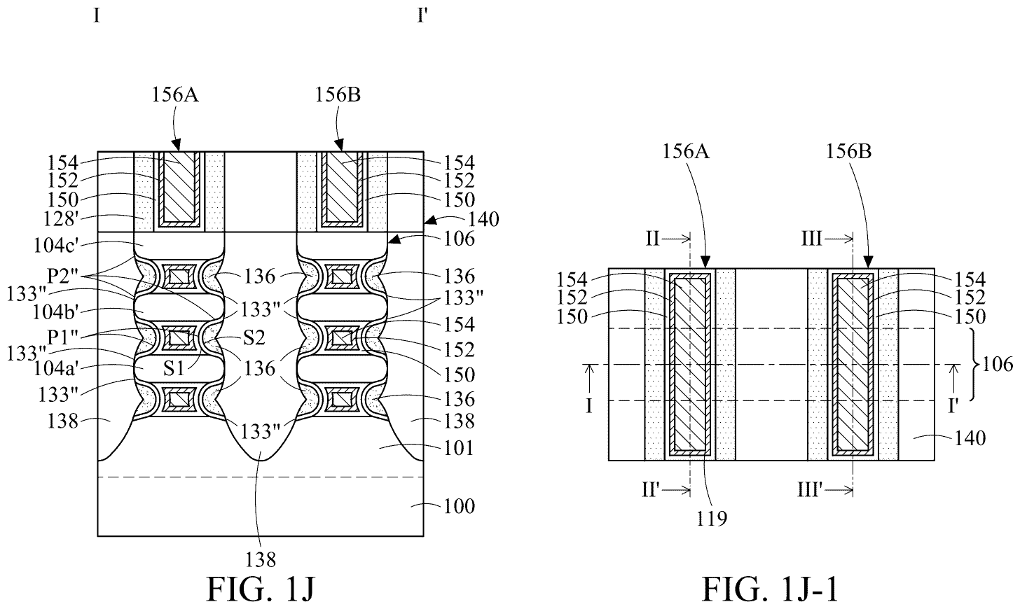

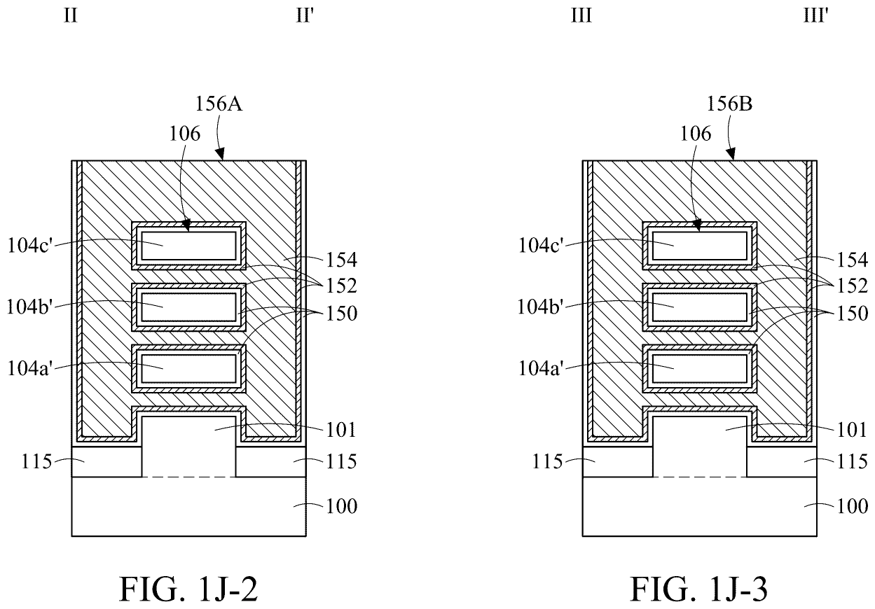

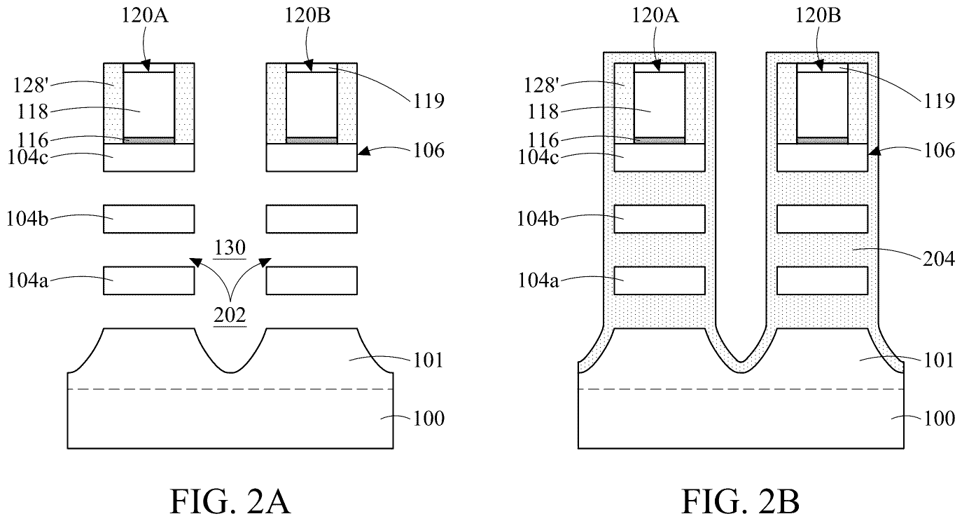

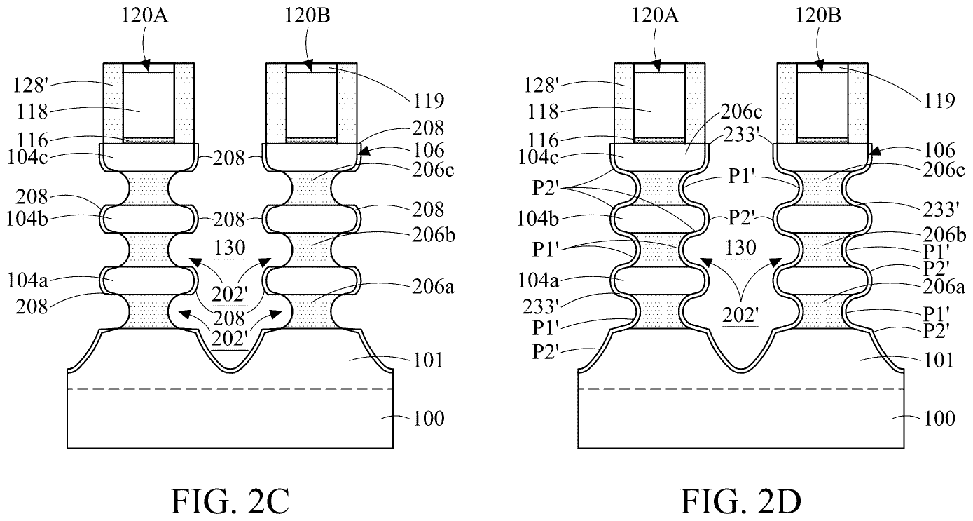

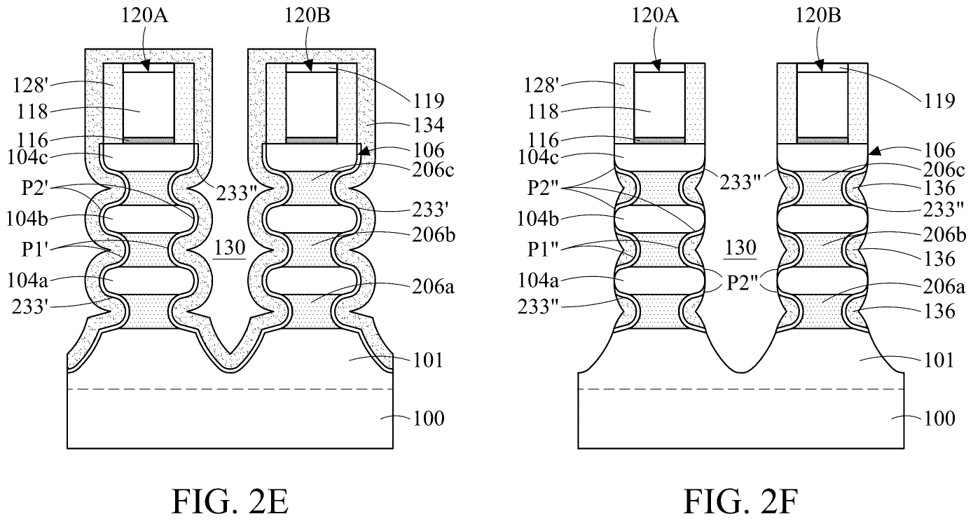

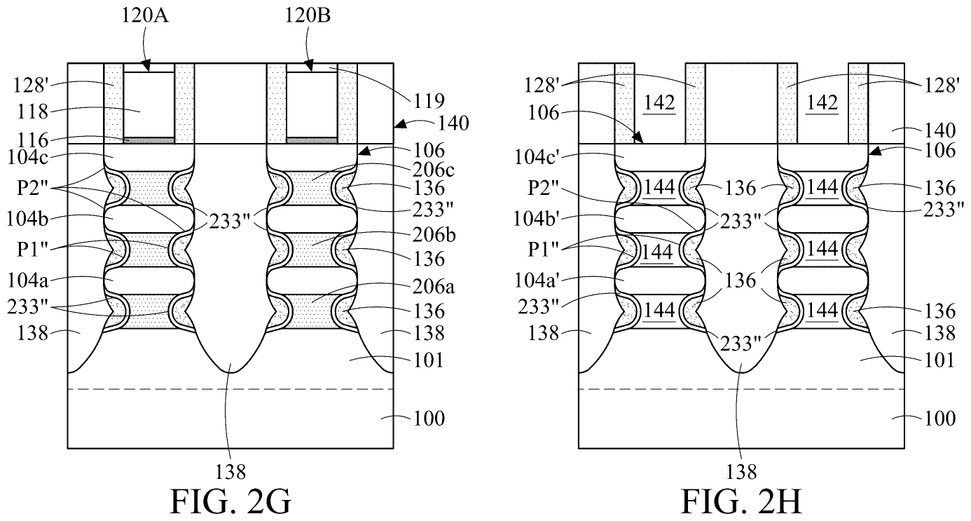

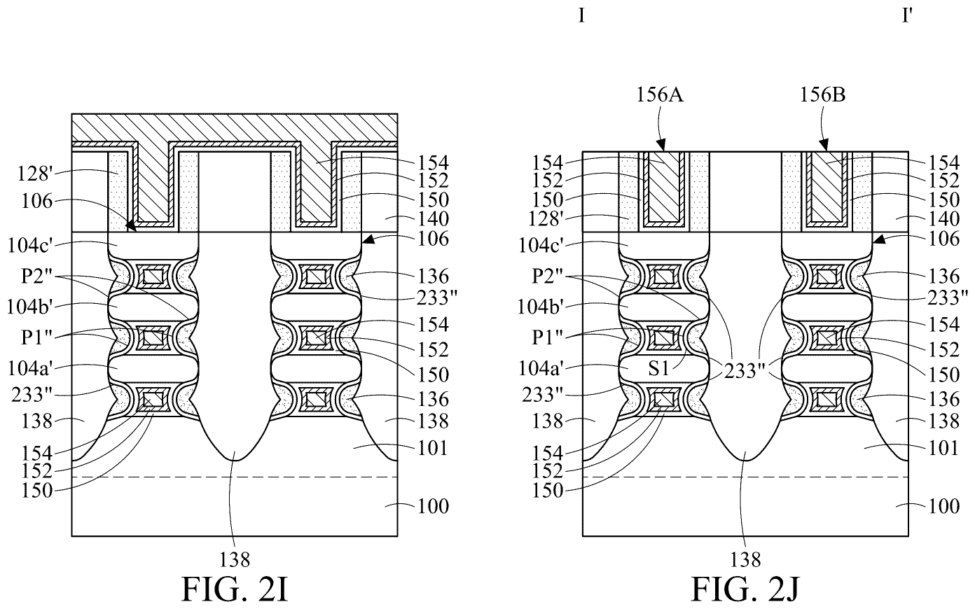

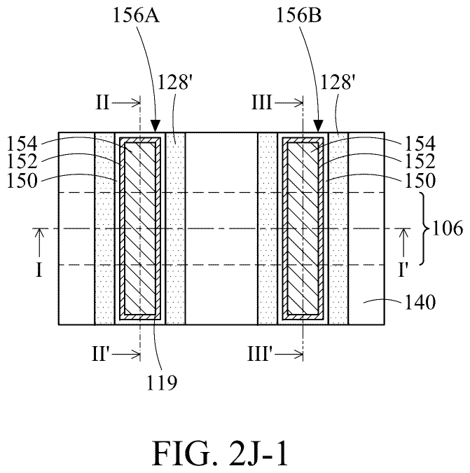

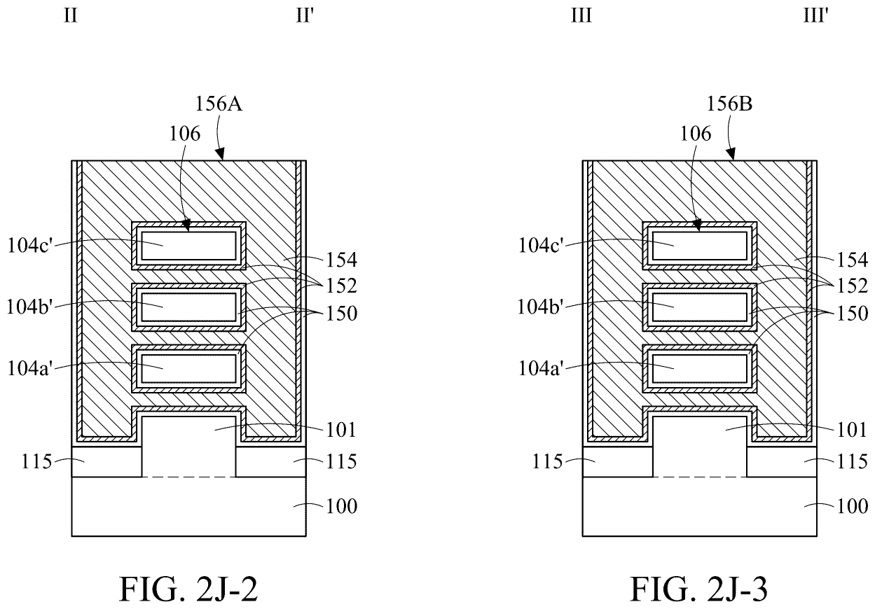

FIGS. 1A-1J are cross-sectional views of various stages of a process for forming a portion of a semiconductor device structure, in accordance with some embodiments. FIG. 1A-1 is a top view of an intermediate stage of a process for forming a portion of a semiconductor device structure, in accordance with some embodiments. In some embodiments, FIG. 1A is a cross-sectional view of the structure taken along the line I-I′ in FIG. 1A-1. FIG. 1A-2 is a cross-sectional view of an intermediate stage of a process for forming a portion of a semiconductor device structure, in accordance with some embodiments. In some embodiments, FIG. 1A-2 is a cross-sectional view of the structure taken along the line II-II′ in FIG. 1A-1. FIG. 1A-3 is a cross-sectional view of an intermediate stage of a process for forming a portion of a semiconductor device structure, in accordance with some embodiments. In some embodiments, FIG. 1A-3 is a cross-sectional view of the structure taken along the line III-III′ in FIG. 1A-1.

In some embodiments, a semiconductor substrate 100 is received or provided. In some embodiments, the semiconductor substrate 100 is a bulk semiconductor substrate, such as a semiconductor wafer. The semiconductor substrate 100 may include silicon or other elementary semiconductor materials such as germanium. The semiconductor substrate 100 may be un-doped or doped (e.g., p-type, n-type, or a combination thereof). In some embodiments, the semiconductor substrate 100 includes an epitaxially grown semiconductor layer on a dielectric layer. The epitaxially grown semiconductor layer may be made of silicon germanium, silicon, germanium, one or more other suitable materials, or a combination thereof.

In some other embodiments, the semiconductor substrate 100 includes a compound semiconductor. For example, the compound semiconductor includes one or more III-V compound semiconductors having a composition defined by the formula Alₓ₁Gaₓ₂Inₓ₃As_{Y1}P_{Y2}N_{Y3}Sb_{Y4}, where X1, X2, X3, Y1, Y2, Y3, and Y4 represent relative proportions. Each of them is greater than or equal to zero, and added together they equal 1. The compound semiconductor may include silicon carbide, gallium arsenide, indium arsenide, indium phosphide, one or more other suitable compound semiconductors, or a combination thereof. Other suitable substrate including II-VI compound semiconductors may also be used.

In some embodiments, the semiconductor substrate 100 is an active layer of a semiconductor-on-insulator (SOI) substrate. The SOI substrate may be fabricated using a separation by implantation of oxygen (SIMOX) process, a wafer bonding process, another applicable method, or a combination thereof. In some other embodiments, the semiconductor substrate 100 includes a multi-layered structure. For example, the semiconductor substrate 100 includes a silicon-germanium layer formed on a bulk silicon layer.

Afterwards, in some embodiments, a semiconductor stack having multiple semiconductor layers is formed over the semiconductor substrate 100, in accordance with some embodiments. In some embodiments, the semiconductor stack includes multiple semiconductor layers 102a, 102b, and 102c. The semiconductor stack also includes multiple semiconductor layers 104a, 104b, and 104c. In some embodiments, the semiconductor layers 102a-102c and the semiconductor layers 104a-104c are laid out in an alternating manner.

In some embodiments, the semiconductor layers 102a-102c function as sacrificial layers that will be removed in a subsequent process to release the semiconductor layers 104a-104c. The semiconductor layers 104a-104c that are released from multiple semiconductor nanostructures. The released semiconductor nanostructures constructed by the semiconductor layers 104a-104c may function as the channel structures of one or more transistors.

In some embodiments, the semiconductor layers 104a-104c that will be used to form channel structures are made of a material that is different than that of the semiconductor layers 102a-102c. In some embodiments, the semiconductor layers 104a-104c are made of or include silicon, germanium, another suitable material, or a combination thereof. In some embodiments, the semiconductor layers 102a-102c are made of or include silicon germanium. In some other embodiments, the semiconductor layers 104a-104c are made of silicon germanium, and the semiconductor layers 102a-102c are made of silicon germanium with different atomic concentration of germanium than that of the semiconductor layers 104a-104c. Due to the different compositions, different etching selectivity and/or different oxidation rates during subsequent processing may be achieved between the semiconductor layers 102a-102c and the semiconductor layers 104a-104c.

The present disclosure contemplates that the semiconductor layers 102a-102c and the semiconductor layers 104a-104c include any combination of semiconductor materials that can provide desired etching selectivity, desired oxidation rate differences, and/or desired performance characteristics (e.g., materials that maximize current flow).

In some embodiments, the semiconductor layers 102a-102c and 104a-104c are formed using multiple epitaxial growth operations. Each of the semiconductor layers 102a-102c and 104a-104c may be formed using a selective epitaxial growth (SEG) process, a CVD process (e.g., a vapor-phase epitaxy (VPE) process, a low-pressure chemical vapor deposition (LPCVD) process, and/or an ultra-high vacuum CVD (UHV-CVD) process), a molecular beam epitaxy process, one or more other applicable processes, or a combination thereof.

In some embodiments, the semiconductor layers 102a-102c and 104a-104c are grown in-situ in the same process chamber. In some embodiments, the growth of the semiconductor layers 102a-102c and 104a-104c are alternately and sequentially performed in the same process chamber to complete the formation of the semiconductor stack. In some embodiments, the vacuum of the process chamber is not broken before the epitaxial growth of the semiconductor stack is accomplished.

Afterwards, hard mask elements are formed over the semiconductor stack to assist in a subsequent patterning of the semiconductor stack. One or more photolithography processes and one or more etching processes are used to pattern the semiconductor stack into multiple fin structures 106. As shown in FIGS. 1A, 1A-1, 1A-2, and 1A-3, one of the fin structures 106 is shown. The fin structures 106 may be patterned by any suitable method. For example, the fin structures 106 may be patterned using one or more photolithography processes, including double-patterning or multi-patterning processes. Double-patterning or multi-patterning processes may combine photolithography and self-aligned processes, allowing patterns to be created that have, for example, pitches smaller than what is otherwise obtainable using a single, direct photolithography process.

The semiconductor stack is partially removed to form multiple fin structures 106 (including the fin structure 106 shown in FIGS. 1A, 1A-1, 1A-2, and 1A-3) and multiple trenches. As shown in FIGS. 1A, 1A-2, and 1A-3, the fin structure 106 may include portions of the semiconductor layers 102a-102c and 104a-104c and multiple semiconductor fins (including the semiconductor fin 101 shown in FIGS. 1A, 1A-2, and 1A-3). The semiconductor substrate 100 may also be partially removed during the etching process that forms the fin structures 106. Protruding portions of the semiconductor substrate 100 that remain form the semiconductor fin 101.

Afterwards, as shown in FIGS. 1A-2 and 1A-3, an isolation structure 115 is formed to surround lower portions of the fin structure 106, in accordance with some embodiments. In some embodiments, the isolation structure 115 includes multiple sub-layers that is adjacent to the semiconductor fin 101.

In some embodiments, one or more dielectric layers are deposited over the fin structure 106 and the semiconductor substrate 100 to overfill the trenches. The dielectric layers may be made of or include silicon oxide, silicon oxynitride, borosilicate glass (BSG), phosphoric silicate glass (PSG), borophosphosilicate glass (BPSG), fluorinated silicate glass (FSG), low-k material, porous dielectric material, one or more other suitable materials, or a combination thereof. The dielectric layers may be deposited using a flowable chemical vapor deposition (FCVD) process, an atomic layer deposition (ALD) process, a chemical vapor deposition (CVD) process, one or more other applicable processes, or a combination thereof.

Afterwards, a planarization process is used to partially remove the dielectric layers. The hard mask element over the fin structure 106 may also function as a stop layer of the planarization process. The planarization process may include a chemical mechanical polishing (CMP) process, a grinding process, a dry polishing process, an etching process, one or more other applicable processes, or a combination thereof.

Afterwards, one or more etching back processes are used to partially remove the dielectric layers. As a result, the remaining portion of the dielectric layers forms the isolation structure 115. Upper portions of the fin structure 106 protrudes from the top surface of the isolation structure 115, as shown in FIGS. 1A-2 and 1A-3.

In some embodiments, the etching back process for forming the isolation structure 115 is carefully controlled to ensure that the topmost surface of the isolation structure 115 is positioned at a suitable height level, as shown in FIGS. 1A-2 and 1A-3. In some embodiments, the topmost surface of the isolation structure 115 is below the bottommost surface of the semiconductor layer 102a that functions as a sacrificial layer.

Afterwards, the hard mask element over the fin structure 106 is removed. Alternatively, in some other embodiments, the hard mask element is removed or consumed during the planarization process and/or the etching back process that forms the isolation structure 115.

Afterwards, dummy gate stacks 120A and 120B are formed to extend across the fin structure 106, as shown in FIGS. 1A, 1A-1, 1A-2, and 1A-3 in accordance with some embodiments. The dummy gate stacks 120A and 120B partially cover and extend across the fin structure 106. In some embodiments, the dummy gate stacks 120A and 120B partially cover the fin structure 106. As shown in FIGS. 1A-2 and 1A-3, the dummy gate stacks 120A and 120B extend across and are wrapped around the fin structure 106.

As shown in FIGS. 1A, 1A-2, and 1A-3, each of the dummy gate stacks 120A and 120B includes a dummy gate dielectric layer 116 and a dummy gate electrode 118. The dummy gate dielectric layer 116 may be made of or include silicon oxide or another suitable material. The dummy gate electrodes 118 may be made of or include polysilicon or another suitable material.

In some embodiments, a dummy gate dielectric material layer and a dummy gate electrode layer are sequentially deposited over the isolation structure 115 and the fin structure 106. The dummy gate dielectric material layer may be deposited using an ALD process, a CVD process, one or more other applicable processes, or a combination thereof. The dummy gate electrode layer may be deposited using a CVD process. Afterwards, the dummy gate dielectric material layer and the dummy gate electrode layer are patterned to form the dummy gate stacks 120A and 120B.

In some embodiments, hard mask elements 119 are used to assist in the patterning process for forming the dummy gate stacks 120A and 120B. With the hard mask elements 119 as an etching mask, one or more etching processes are used to partially remove the dummy gate dielectric material layer and the dummy gate electrode layer. As a result, remaining portions of the dummy gate dielectric material layer and the dummy gate electrode layer form the dummy gate stacks 120A and 120B.

As shown in FIGS. 1A and 1A-1, gate spacers 128′ are then formed over the sidewalls of the dummy gate stacks 120A and 120B, in accordance with some embodiments. In some embodiments, one or more spacer layers are deposited over the dummy gate stacks 120A and 120B and the fin structure 106. The spacer layers extend along the tops and sidewalls of the dummy gate stacks 120A and 120B.

The spacer layers may be made of or include silicon nitride, silicon oxynitride, carbon-containing silicon nitride, carbon-containing silicon oxynitride, silicon oxide, carbon-containing silicon oxide, aluminum oxide, hafnium oxide, one or more other suitable materials, or a combination thereof. In some embodiments, one or more of the spacer layers is/are made of a high-k material. The spacer layers may be deposited using a CVD process, an ALD process, a physical vapor deposition (PVD) process, another applicable process, or a combination thereof.

Afterwards, the spacer layers are partially removed, in accordance with some embodiments. One or more anisotropic etching processes may be used to partially remove the spacer layers. As a result, remaining portions of the spacer layers form the gate spacers 128′. The gate spacers 128′ extend along the sidewalls of the dummy gate stacks 120A and 120B, as shown in FIGS. 1A and 1A-1.

As shown in FIG. 1B, the fin structure 106 is partially removed, in accordance with some embodiments. As a result, multiple recesses 130 are formed. The recesses 130 expose the side edges of the semiconductor layers 102a-102c and 104a-104c. The recesses 130 may be used to contain epitaxial structures (such as source/drain structures) that will be formed later. Source/drain structures (or region(s)) may refer to a source or a drain, individually or collectively dependent upon the context. In some embodiments, the recesses 130 formed in the fin structure 106 are used for containing p-type doped epitaxial structures that will be formed later. In some embodiments, the recesses 130 formed in the fin structure 106B are used for containing n-type doped epitaxial structures that will be formed later.

One or more etching processes may be used to form the recesses 130. In some embodiments, a dry etching process is used to form the recesses 130. Alternatively, a wet etching process may be used to form the recesses 130. The recesses 130 penetrate into the fin structure 106. In some embodiments, the recesses 130 further extend into the semiconductor fin 101, as shown in FIG. 1B.

In some embodiments, the recesses 130 have substantially vertical sidewalls. In these cases, due to the profile of the recesses 130, an upper semiconductor layer (such as the semiconductor layer 104c) is substantially as wide as a lower semiconductor layer (such as the semiconductor layer 104b).

However, embodiments of the disclosure have many variations. In some other embodiments, each of the recesses 130 has slanted sidewalls. Upper portions of the recesses 130 are larger (or wider) than lower portions of the recesses 130. In these cases, due to the profile of the recesses 130, an upper semiconductor layer (such as the semiconductor layer 104c) is shorter than a lower semiconductor layer (such as the semiconductor layer 104b).

Afterwards, as shown in FIG. 1C, the semiconductor layers 102a-102c are laterally etched, in accordance with some embodiments. As a result, the side edges of the semiconductor layers 102a-102c retreat from the side edges of the semiconductor layers 104a-104c. The side edges of the semiconductor layers 102a-102c are pulled back. As shown in FIG. 1C, recesses 132 are formed due to the lateral etching of the semiconductor layers 102a-102c. The recesses 132 may be used to contain protective elements and inner spacers that will be formed later. The semiconductor layers 102a-102c may be laterally etched using a wet etching process, a dry etching process, or a combination thereof. In some other embodiments, the semiconductor layers 102a-102c are partially oxidized before being laterally etched.

As shown in FIG. 1C, the surface portions of the semiconductor layers 102a-102c and 104a-104c and the semiconductor fin 101 are oxidized and become native oxide layers 133, in accordance with some embodiments. The native oxide layers 133 are naturally grown at the surface portions of the semiconductor layers 102a-102c and 104a-104c. Each of the native oxide layers 133 has multiple portions including first portions P1 of the semiconductor layers 102a-102c and second portions P2 of the semiconductor layers 104a-104c.

In some embodiments, the compositions of the first portions P1 and the second portions P2 are different. In some embodiments, the semiconductor layers 102a-102c are made of silicon germanium. The exposed surface portions of the semiconductor layers 102a-102c are oxidized to form the first portions P1. The first portions P1 may be made of silicon-germanium oxide. In some embodiments, the semiconductor layers 104a-104c are made of silicon. The exposed surface portions of the semiconductor layers 104a-104c are oxidized to form the second portions P2. The second portions P2 may be made of silicon oxide.

Afterwards, a modifying treatment is used to modifying the surface portions of the semiconductor layers 102a-102c and 104a-104c, in accordance with some embodiments. As a result, the surface portions of the semiconductor layers 102a-102c and 104a-104c are transformed into modified layers 133′, as shown in FIG. 1D in accordance with some embodiments. During the modifying treatment, modifying elements are introduced into the native oxide layers 133 to form the modified layers 133′. As a result, the density of the modified layers 133′ is increased to be higher than that of the native oxide layers 133. The modifying elements may include nitrogen, carbon, boron, another suitable material, or a combination thereof.

The modified layers 133′ has opposite sidewalls S11 and S22, in accordance with some embodiments. The sidewall S11 faces the semiconductor layers 102a-102c and 104a-104c, in accordance with some embodiments. The sidewall S22 faces away from the semiconductor layers 102a-102c and 104a-104c, in accordance with some embodiments. The atomic concentration of the modifying elements (e.g., nitrogen, carbon, or boron) of the modified layers 133′ continuously increases from the sidewall S11 to the sidewall S22.

The modifying treatment enhances the etching resistance of the modified layers 133′, making them more resistant to the etchant used for removing semiconductor materials and/or oxide materials. The modified layers 133′ may have a thickness that is in a range from about 3 angstroms to about 15 angstroms.

In some embodiments, the modifying elements include nitrogen. The structure shown in FIG. 1C is disposed in a nitrogen-containing atmosphere to introduce nitrogen into the native oxide layers 133. In some embodiments, a nitrogen-containing gas such as NH₃ gas is introduced into a reaction chamber where the structure shown in FIG. 1C is disposed. As a result, nitrogen from the NH₃ gas may be introduced into the native oxide layers 133. As a result, the modified layers 133′ are formed, as shown in FIG. 1D. In some embodiments, the atomic concentration of nitrogen of the modified layer 133′ gradually decreases along a direction from the outer surface of the modified layer 133′ (adjacent to the recess 130) towards the inner surface of the modified layer 133′ (adjacent to the semiconductor layers 102a-102c or 104a-104c).

In some embodiments, the surface portions of the semiconductor layers 102a-102c and 104a-104c (or the native oxide layers 133) are exposed to the nitrogen-containing gas such as NH₃ gas at an elevated temperature. In some embodiments, the native oxide layers 133 are exposed to NH₃ gas at a temperature in a range from about 550 degrees C. to about 600 degrees C. for a duration of about 10 minutes to about 2 hours.

Each of the modified layer 133′ has multiple portions including first portions P1′ near the semiconductor layers 102a-102c and second portions P2′ near the semiconductor layers 104a-104c. In some embodiments, the compositions of the first portions P1′ and the second portions P2′ are different. In some embodiments, the semiconductor layers 102a-102c are made of silicon germanium. The first portions P1′ may be made of nitrogen-containing silicon-germanium oxide. The atomic concentration of nitrogen of the first portions P1′ may be in a range from about 5% to about 25%. In some embodiments, the semiconductor layers 104a-104c are made of silicon. The second portions P2 may be made of nitrogen-containing silicon oxide.

In some embodiments, the modifying elements include carbon. The structure shown in FIG. 1C is disposed in a carbon-containing atmosphere to introduce carbon into the native oxide layers 133. In some embodiments, a carbon-containing gas such as C₃H₆ gas is introduced into a reaction chamber where the structure shown in FIG. 1C is disposed. As a result, carbon from the C₃H₆ gas may be introduced into the native oxide layers 133. As a result, the modified layers 133′ are formed, as shown in FIG. 1D. In some embodiments, the atomic concentration of carbon of the modified layer 133′ gradually decreases along a direction from the outer surface of the modified layer 133′ (adjacent to the recess 130) towards the inner surface of the modified layer 133′ (adjacent to the semiconductor layers 102a-102c or 104a-104c).

In some embodiments, the surface portions of the semiconductor layers 102a-102c and 104a-104c (or the native oxide layers 133) are exposed to the carbon-containing gas such as C₃H₆ gas at an elevated temperature. In some embodiments, the native oxide layers 133 are exposed to C₃H₆ gas at a temperature in a range from about 550 degrees C. to about 650 degrees C. for a duration of about 10 minutes to about 2 hours.

Each of the modified layer 133′ has multiple portions including first portions P1′ near the semiconductor layers 102a-102c and second portions P2′ near the semiconductor layers 104a-104c. In some embodiments, the compositions of the first portions P1′ and the second portions P2′ are different. In some embodiments, the semiconductor layers 102a-102c are made of silicon germanium. The first portions P1′ may be made of carbon-containing silicon-germanium oxide. The atomic concentration of carbon of the first portions P1′ may be in a range from about 1% to about 15%. In some embodiments, the semiconductor layers 104a-104c are made of silicon. The second portions P2 may be made of carbon-containing silicon oxide.

In some embodiments, the modifying elements include boron. The structure shown in FIG. 1C is disposed in a boron-containing atmosphere to introduce boron into the native oxide layers 133. In some embodiments, a boron-containing plasma is introduced into a reaction chamber where the structure shown in FIG. 1C is disposed. As a result, boron from the boron-containing plasma may be introduced into the native oxide layers 133. In some embodiments, an ion implantation process is used to introduce boron into the native oxide layers 133. As a result, the modified layers 133′ are formed, as shown in FIG. 1D. In some embodiments, the atomic concentration of boron of the modified layer 133′ gradually decreases along a direction from the outer surface of the modified layer 133′ (adjacent to the recess 130) towards the inner surface of the modified layer 133′ (adjacent to the semiconductor layers 102a-102c or 104a-104c).

Each of the modified layer 133′ has multiple portions including first portions P1′ near the semiconductor layers 102a-102c and second portions P2′ near the semiconductor layers 104a-104c. In some embodiments, the compositions of the first portions P1′ and the second portions P2′ are different. In some embodiments, the semiconductor layers 102a-102c are made of silicon germanium. The first portions P1′ may be made of boron-containing silicon-germanium oxide. The atomic concentration of boron of the first portions P1′ may be in a range from about 0.5% to about 1%. In some embodiments, the semiconductor layers 104a-104c are made of silicon. The second portions P2 may be made of boron-containing silicon oxide.

Many variations and/or modifications can be made to embodiments of the disclosure. In some other embodiments, two or more kinds of modifying elements are introduced into the surface portions of the semiconductor layers 102a-102c and 104a-104c. As a result, the obtained modified layers may contain two or more kinds of modifying elements. The etching resistance of the modified layers may be improved.

As shown in FIG. 1E, an insulating layer 134 is deposited over the structure shown in FIG. 1D, in accordance with some embodiments. The insulating layer 134 covers the dummy gate stacks 120A and 120B and the modified layers 133′ and fills the recesses 132. The insulating layer 134 may be made of or include carbon-containing silicon nitride (SiCN), carbon-containing silicon oxynitride (SiOCN), carbon-containing silicon oxide (SiOC), silicon oxide, silicon nitride, aluminum oxide, hafnium oxide, one or more other suitable materials, or a combination thereof. In some embodiments, the insulating layer 134 has a higher atomic concentration of nitrogen than that of the modified layers 133′. In some embodiments, the insulating layer 134 has a higher atomic concentration of carbon than that of the modified layers 133′. In some embodiments, the insulating layer 134 has a lower atomic concentration of boron than that of the modified layers 133′.

In some embodiments, the insulating layer is a single layer. In some other embodiments, the insulating layer includes multiple sub-layers. Some of the sub-layers may be made of different materials and/or contain different compositions. The insulating layer may be deposited using a CVD process, an ALD process, one or more other applicable processes, or a combination thereof.

Afterwards, one or more etching processes are used to partially remove the insulating layer 134 and the modified layers 133′, in accordance with some embodiments. The portions of the insulating layer 134 and the modified layers 133′ that are outside of the recesses 132 may be removed. As a result, the remaining portions of the insulating layer 134 form multiple inner spacers 136, as shown in FIG. 1F in accordance with some embodiments. The remaining portions of the modified layers 133′ form multiple protective elements (or modified elements) 133″, as shown in FIG. 1F. The etching process may include a dry etching process, a wet etching process, or a combination thereof. In some embodiments, the compositions of the inner spacers 136 and the gate spacers 128′ are different, so as to provide etching selectivity between the inner spacers 136 and the gate spacers 128′.

As shown in FIG. 1F, the inner spacers 136 are separated from the side edges of the semiconductor layers 102a-102c by the protective elements 133″. The protective elements 133″ and the inner spacers 136 may work together to prevent subsequently formed epitaxial structures (such as source/drain structures) from being damaged during a subsequent process for removing the semiconductor layers 102a-102c. In some embodiments, the inner spacers 136 are made of a low-k material that has a lower dielectric constant than that of silicon oxide. In these cases, the inner spacers 136 may also be used to reduce parasitic capacitance between the subsequently formed source/drain structures and the gate stacks. As a result, the operation speed of the semiconductor device structure may be improved.

In some embodiments, after the etching process for forming the inner spacers 136 and the protective elements 133″, portions of the semiconductor fin 101 originally covered by the insulating layer are exposed by the recesses 130, as shown in FIG. 1F. The side edges of the semiconductor layers 104a-104c are exposed by the recesses 130, as shown in FIG. 1F.

As shown in FIG. 1F, each of the protective elements 133″ has a first portion P1″ and a second portion P2″. The first portion P1″ is adjacent to one of the semiconductor layers 102a-102c, and the second portion P2″ is adjacent to the semiconductor layers 104a-104c nearby. The first portion P1″ of the protective element 133″ may be made of or include nitrogen-containing silicon-germanium oxide, carbon-containing silicon-germanium oxide, boron-containing silicon-germanium oxide, another suitable material, or a combination thereof. The second portion P2″ of the protective element 133″ may be made of or include nitrogen-containing silicon oxide, carbon-containing silicon oxide, boron-containing silicon oxide, another suitable material, or a combination thereof. In some embodiments, the second portion P2″ of the protective element 133″ has a higher atomic concentration of nitrogen than that of the first portion P1″. In some embodiments, the second portion P2″ of the protective element 133″ has a higher atomic concentration of carbon than that of the first portion P1″. In some embodiments, the second portion P2″ of the protective element 133″ has a higher atomic concentration of boron than that of the first portion P1″.

As shown in FIG. 1G, epitaxial structures 138 are formed on the side edges of semiconductor layers 104a-104c and the semiconductor fin 101, in accordance with some embodiments. The epitaxial structures 138 may function as source/drain structures (or regions). Source/drain structures (or region(s)) may refer to a source or a drain, individually or collectively dependent upon the context. In some embodiments, the epitaxial structures 138 fill the recesses 130. In some embodiments, the epitaxial structures 138 overfill the recesses 130 to ensure fully contact between the epitaxial structures 138 and the side edges of the semiconductor layer 104c nearby. In some other embodiments, the epitaxial structures 138 partially fill the recesses 130. In some embodiments, the epitaxial structures 138 are in direct contact with the inner spacers 136 and the protective elements 133″, as shown in FIG. 1G.

In some embodiments, the epitaxial structures 138 connect to some of the semiconductor layers 104a-104c. Some of the semiconductor layers 104a-104c are sandwiched between the epitaxial structures 138. In some embodiments, the epitaxial structures 138 are n-type doped epitaxial structures. The epitaxial structures 138 may include epitaxially grown silicon, epitaxially grown silicon germanium (SiGe), or another suitable epitaxially grown semiconductor material. In some other embodiments, the epitaxial structures 138 are p-type doped epitaxial structures. The epitaxial structures 138 may include epitaxially grown silicon germanium (SiGe), epitaxially grown silicon, or another suitable epitaxially grown semiconductor material.

In some embodiments, the epitaxial structures 138 are formed using a selective epitaxial growth (SEG) process, a CVD process (e.g., a vapor-phase epitaxy (VPE) process, a low-pressure chemical vapor deposition (LPCVD) process, and/or an ultra-high vacuum CVD (UHV-CVD) process), a molecular beam epitaxy process, one or more other applicable processes, or a combination thereof. In some embodiments, the formation of the epitaxial structures 138 involves one or more etching processes that are used to fine-tune the shapes of the epitaxial structures 138.

In some embodiments, the epitaxial structures 138 are doped with one or more suitable n-type dopants. For example, the epitaxial structures 138 are Si source/drain features that are doped with phosphor (P), antimony (Sb), arsenic (As) or another suitable dopant. In some other embodiments, the epitaxial structures 138 are doped with one or more suitable p-type dopants. For example, the epitaxial structures 138 are SiGe source/drain features that are doped with boron (B), gallium (Ga), indium (In), or another suitable dopant or another suitable dopant. In some embodiments, each of the epitaxial structures 138 has a first region and a second region over the first region. The second region may have a greater dopant concentration than that of the first region.

In some embodiments, the epitaxial structures 138 are doped in-situ during their epitaxial growth. The initial reaction gas mixture for forming the epitaxial structures 138 contains dopants. In some other embodiments, the epitaxial structures 138 are not doped during the growth of the epitaxial structures 138. Instead, after the formation of the epitaxial structures 138, the epitaxial structures 138 are doped in a subsequent process. In some embodiments, the doping is achieved by using an ion implantation process, a plasma immersion ion implantation process, a gas and/or solid source diffusion process, one or more other applicable processes, or a combination thereof. In some embodiments, the epitaxial structures 138 are further exposed to one or more annealing processes to activate the dopants. For example, a rapid thermal annealing process is used.

Afterwards, a dielectric layer 140 are formed over the epitaxial structures 138 to laterally surround the dummy gate stacks 120A and 120B, as shown in FIG. 1G in accordance with some embodiments. In some embodiments, before the formation of the dielectric layer 140, a contact etch stop layer is formed over the epitaxial structures 138. The contact etch stop layer may further extend along the sidewalls of the dummy gate stacks 120A and 120B. The contact etch stop layer may be made of or include silicon nitride, silicon oxynitride, silicon carbide, aluminum oxide, another suitable material, or a combination thereof. The dielectric layer 140 may be made of or include silicon oxide, silicon oxynitride, borosilicate glass (BSG), phosphoric silicate glass (PSG), borophosphosilicate glass (BPSG), fluorinated silicate glass (FSG), low-k material, porous dielectric material, another suitable material, or a combination thereof.

In some embodiments, an etch stop material layer and a dielectric material layer are sequentially deposited. The etch stop material layer may be deposited using a CVD process, an ALD process, a PVD process, one or more other applicable processes, or a combination thereof. The dielectric material layer may be deposited using an FCVD process, a CVD process, an ALD process, another applicable process, or a combination thereof.

Afterwards, a planarization process is used to partially remove the etch stop material layer and the dielectric material layer. As a result, the remaining portions of the etch stop material layer and the dielectric material layer respectively form the contact etch stop layer and the dielectric layer 140, as shown in FIG. 1G. The planarization process may include a CMP process, a grinding process, an etching process, a dry polishing process, one or more other applicable processes, or a combination thereof.

Afterwards, as shown in FIG. 1H, the dummy gate electrodes 118 are removed to form trenches 142 using one or more etching processes, in accordance with some embodiments. The trenches 142 are surrounded by the dielectric layer 140.

As shown in FIG. 1H, the dummy gate dielectric layer 116 and the semiconductor layers 102a-102c (which function as sacrificial layers) are also removed, in accordance with some embodiments. In some embodiments, one or more etching processes are used to remove the dummy gate dielectric layer 116 and the semiconductor layers 102a-102c. As a result, recesses 144 are formed, as shown in FIG. 1H.

In some embodiments, the native oxide layers 133 have been modified and transformed into the protective elements 133″ that have high etching resistance to the etchant (e.g., wet etching etchant including dilute HF, HF, H₂SO₄, H₃PO₄, or NH₄F and dry etching etchant including O₂ ash, O₂ plasma, or CF₄ radical) used for removing the semiconductor layers 102a-102c. Therefore, the epitaxial structures 138 are protected by the protective elements 133″ and prevented from being damaged. The reliability and performance of the semiconductor device structure are thus improved.

Due to high etching selectivity, the semiconductor layers 104a-104c are slightly (or substantially not) etched. The remaining portions of the semiconductor layers 104a-104c form multiple semiconductor nanostructures 104a′-104c′. The semiconductor nanostructures 104a′-104c′ are constructed by or made up of the remaining portions of the semiconductor layers 104a-104c. The semiconductor nanostructures 104a′-104c′ suspended over the semiconductor fin 101 may function as the channel structures of transistors.

In some other embodiments, the etchant used for removing the semiconductor layers 102a-102c also slightly removes the semiconductor layers 104a-104c that form the semiconductor nanostructures 104a′-104c′. As a result, the obtained semiconductor nanostructures 104a′-104c′ become thinner after the removal of the semiconductor layers 102a-102c. In some embodiments, each of the semiconductor nanostructures 104a′-104c′ is thinner than the edge portions since the edge portions are surrounded by other elements and thus are prevented from being reached and etched by the etchant.

After the removal of the semiconductor layers 102a-102c (which function as sacrificial layers), the recesses 144 are formed. The recesses 144 connect to the trench 142 and surround each of the semiconductor nanostructures 104a′-104c′. As shown in FIG. 1H, even if the recesses 144 between the semiconductor nanostructures 104a′-104c′ are formed, the semiconductor nanostructures 104a′-104c′ remain held by the neighboring elements including the epitaxial structures 138, the protective elements 133″, and the inner spacers 136. Therefore, after the removal of the dummy gate stacks 120A and 120B and the semiconductor layers 102a-102c (which function as sacrificial layers), the released semiconductor nanostructures 104a′-104c′ are prevented from falling.

During the removal of the semiconductor layers 102a-102c (which function as sacrificial layers), the protective elements 133″ and the inner spacers 136 prevent the epitaxial structures 138 from being etched or damaged. The quality and reliability of the semiconductor device structure are improved.

As shown in FIG. 1I, metal gate stack layers are formed to fill the trenches 142 and the recesses 144, in accordance with some embodiments. The metal gate stack layers may include a gate dielectric layer 150, a work function layer 152, and a conductive filling layer 154. The metal gate stack layers extend into the recesses 144 to wrap around each of the semiconductor nanostructures 104a′-104c′.

In some embodiments, the gate dielectric layer 150 is made of or includes a dielectric material with high dielectric constant (high-K). The gate dielectric layer 150 may be made of or include hafnium oxide, zirconium oxide, aluminum oxide, hafnium dioxide-alumina alloy, hafnium silicon oxide, hafnium silicon oxynitride, hafnium tantalum oxide, hafnium titanium oxide, hafnium zirconium oxide, one or more other suitable high-K materials, or a combination thereof. The gate dielectric layer 150 may be deposited using an ALD process, a CVD process, one or more other applicable processes, or a combination thereof.

In some embodiments, before the formation of the gate dielectric layer 150, an interfacial layers are formed on the surfaces of the semiconductor nanostructures 104a′-104c′. The interfacial layers are very thin and are made of, for example, silicon oxide or germanium oxide. In some embodiments, the interfacial layers are formed by applying an oxidizing agent on the surfaces of the semiconductor nanostructures 104a′-104c′. For example, a hydrogen peroxide-containing liquid may be applied or provided on the surfaces of the semiconductor nanostructures 104a′-104c′ so as to form the interfacial layers.

The work function layer 152 may be used to provide the desired work function for transistors to enhance device performance including improved threshold voltage. In some embodiments, the work function layer surrounding the semiconductor nanostructures 104a′-104c′ is used for forming a PMOS device. In these cases, the work function layer 152 is a p-type work function layer. The p-type work function layer is capable of providing a work function value suitable for the device, such as equal to or greater than about 4.8 eV.

The p-type work function layer may include metal, metal carbide, metal nitride, other suitable materials, or a combination thereof. For example, the p-type metal includes tantalum nitride, tungsten nitride, titanium, titanium nitride, one or more other suitable materials, or a combination thereof.

In some embodiments, the work function layer surrounding the semiconductor nanostructures 104a′-104c′ is used for forming an NMOS device. The work function layer 152 is an n-type work function layer. The n-type work function layer is capable of providing a work function value suitable for the device, such as equal to or less than about 4.5 eV.

The n-type work function layer may include metal, metal carbide, metal nitride, or a combination thereof. For example, the n-type work function layer includes titanium nitride, tantalum, tantalum nitride, one or more other suitable materials, or a combination thereof. In some embodiments, the n-type work function is an aluminum-containing layer. The aluminum-containing layer may be made of or include TiAIC, TiAlO, TiAIN, one or more other suitable materials, or a combination thereof.

The work function layer may also be made of or include hafnium, zirconium, titanium, tantalum, aluminum, metal carbides (e.g., hafnium carbide, zirconium carbide, titanium carbide, aluminum carbide), aluminides, ruthenium, palladium, platinum, cobalt, nickel, conductive metal oxides, or a combinations thereof. The thickness and/or the compositions of the work function layer may be fine-tuned to adjust the work function level.

The work function layer may be deposited over the gate dielectric layer 150 using an ALD process, a CVD process, a PVD process, an electroplating process, an electroless plating process, one or more other applicable processes, or a combination thereof. In some embodiments, the formation of the work function layer involves one or more patterning processes. As a result, the n-type work function layer and the p-type work function layer are selectively formed over different regions.

In some embodiments, a barrier layer is formed before the work function layer 152 to interface the gate dielectric layer 150 with the subsequently formed work function layer. The barrier layer may also be used to prevent diffusion between the gate dielectric layer 150 and the subsequently formed work function layer 152. The barrier layer may be made of or include a metal-containing material. The metal-containing material may include titanium nitride, tantalum nitride, one or more other suitable materials, or a combination thereof. The barrier layer may be deposited using an ALD process, a CVD process, a PVD process, an electroplating process, an electroless plating process, one or more other applicable processes, or a combination thereof.

In some embodiments, the conductive filling layer 154 is made of or include a metal material. The metal material may include tungsten, aluminum, copper, cobalt, one or more other suitable materials, or a combination thereof. The conductive filling layer 154 may be deposited over the work function layer 152 using a CVD process, an ALD process, a PVD process, an electroplating process, an electroless plating process, a spin coating process, one or more other applicable processes, or a combination thereof.

In some embodiments, a blocking layer is formed over the work function layer 152 before the formation of the conductive filling layer 154. The blocking layer may be used to prevent the subsequently formed conductive filling layer 154 from diffusing or penetrating into the work function layer 152. The blocking layer may be made of or include tantalum nitride, titanium nitride, one or more other suitable materials, or a combination thereof. The blocking layer may be deposited using an ALD process, a PVD process, an electroplating process, an electroless plating process, one or more other applicable processes, or a combination thereof.

FIG. 1J-1 is a top view of an intermediate stage of a process for forming a portion of a semiconductor device structure, in accordance with some embodiments. In some embodiments, FIG. 1J is a cross-sectional view of the structure taken along the line I-I′ in FIG. 1J-1. FIG. 1J-2 is a cross-sectional view of an intermediate stage of a process for forming a portion of a semiconductor device structure, in accordance with some embodiments. In some embodiments, FIG. 1J-2 is a cross-sectional view of the structure taken along the line II-II′ in FIG. 1J-1. FIG. 1J-3 is a cross-sectional view of an intermediate stage of a process for forming a portion of a semiconductor device structure, in accordance with some embodiments. In some embodiments, FIG. 1J-3 is a cross-sectional view of the structure taken along the line III-III′ in FIG. 1J-1.

Afterwards, a planarization process is performed to remove the portions of the metal gate stack layers outside of the trenches 142 and the recesses 144, in accordance with some embodiments. As a result, the remaining portions of the metal gate stack layers form the metal gate stacks 156A and 156B, as shown in FIGS. 1J, 1J-1, 1J-2, and 1J-3 in accordance with some embodiments. The planarization process may include a CMP process or another applicable process.

In some other embodiments, the conductive filling layer 154 does not extend into the recesses 144 since the recesses 144 are small and have been filled with other elements such as the gate dielectric layer 150 and the work function layer 152. However, embodiments of the disclosure are not limited thereto.

As shown in FIG. 1J, each of the protective element 133″ has a first surface S1 next to the metal gate stack 156A or 156B and a second surface S2 next to the respective inner spacer 136. In some embodiments, the atomic concentration of the modifying element (such as nitrogen, carbon, and/or boron) at the second surface S2 is higher than that at the first surface S1. In some embodiments, the atomic concentration of the modifying element (such as nitrogen, carbon, and/or boron) gradually increases along a direction from the first surface S1 towards the second surface S2.

Many variations and/or modifications can be made to embodiments of the disclosure. FIGS. 2A-2J are cross-sectional views of various stages of a process for forming a portion of a semiconductor device structure, in accordance with some embodiments.

In some embodiments, a structure that is the same as or similar to the structure shown in FIG. 1B is formed. Afterwards, the semiconductor layers 102a-102c, which serve as sacrificial layers, are removed. As a result, the structure shown in FIG. 2A is formed, in accordance with some embodiments. One or more etching processes may be used to remove the semiconductor layers 102a-102c. After the removal of the semiconductor layers 102a-102c, multiple recesses 202 are formed, as shown in FIG. 2A. The semiconductor layers 104a-104c are released from the semiconductor layers 102a-102c. With the support of the dummy gate stacks 120A and 120B, the semiconductor layers 104a-104c are securely held in place.

As shown in FIG. 2B, a dielectric layer 204 is deposited to overfill the recesses 202 and to surround the semiconductor layers 104a-104c, in accordance with some embodiments. The dielectric layer 204 may function as a sacrificial layer and will be removed later. The dielectric layer 204 may be made of an oxide material. The dielectric layer 204 may be made of or include silicon oxide, silicon oxynitride, another suitable material, or a combination thereof. The dielectric layer 204 may be deposited using a CVD process, an ALD process, another applicable process, or a combination thereof.

As shown in FIG. 2C, the dielectric layer 204 is partially removed, in accordance with some embodiments. The portion of the dielectric layer 204 outside of the recesses 202 are removed. Afterwards, the dielectric layer 204 are further laterally etched to form multiple recesses 202′. As a result, the remaining portions of the dielectric layer 204 form multiple dielectric sacrificial layers 206a, 206b, and 206c, as shown in FIG. 2C. The side edges of the dielectric sacrificial layers 206a, 206b, and 206c retreat from the side edges of the semiconductor layers 104a-104c.

In some embodiments, similar to the embodiments illustrated in FIG. 1C, multiple native oxide layers 208 are formed at the surface portions of the semiconductor layers 104a-104c and the semiconductor fin 101. In some embodiments, the semiconductor layers 104a-104c are made of silicon, and the native oxide layers 208 are made of silicon oxide.

As shown in FIG. 2D, similar to the embodiments illustrated in FIG. 1D, a modifying treatment is used to turn the surface portions of the dielectric sacrificial layers 206a-206c and the surface portions of the semiconductor layers 104a-104c (i.e., the native oxide layers 208) into modified layer 233′. The formation method of the modified layers 233′ may be the same as or similar to that of the modified layer 133′ illustrated in FIG. 1D. The modifying treatment enhances the etching resistance of the modified layers 233′, making them more resistant to the etchant used for removing semiconductor materials and/or oxide materials. The modified layers 233′ may have a thickness that is in a range from about 3 angstroms to about 15 angstroms.

In some embodiments, the modifying elements include nitrogen. The structure shown in FIG. 2C is disposed in a nitrogen-containing atmosphere to introduce nitrogen into the surface portions of the semiconductor layers 104a-104c (i.e., the native oxide layers 208) and the surface portions of the dielectric sacrificial layers 206a-206c. In some embodiments, a nitrogen-containing gas such as NH₃ gas is introduced into a reaction chamber where the structure shown in FIG. 2C is disposed. As a result, nitrogen from the NHg gas may be introduced. As a result, the modified layers 233′ are formed, as shown in FIG. 2D. In some embodiments, the atomic concentration of nitrogen of the modified layer 233′ gradually decreases along a direction from the outer surface of the modified layer 233′ (adjacent to the recess 130) towards the inner surface of the modified layer 233′ (adjacent to the semiconductor layers 104a-104c or the dielectric sacrificial layers 206a-206c).

Each of the modified layers 233′ has multiple portions including first portions P1′ near the dielectric sacrificial layers 206a-206c and second portions P2′ near the semiconductor layers 104a-104c. In some embodiments, the compositions of the first portions P1′ and the second portions P2′ are different. In some embodiments, the dielectric sacrificial layers 206a-206c are made of silicon oxide. The first portions P1′ may be made of nitrogen-containing silicon oxide. The atomic concentration of nitrogen of the first portions P1′ may be in a range from about 5% to about 25%. In some embodiments, the semiconductor layers 104a-104c are made of silicon. The second portions P2 may be made of nitrogen-containing silicon oxide. In some embodiments, the atomic concentration of silicon of the second portion P2′ is higher than that of the first portion P1′.

In some embodiments, the modifying elements include carbon. The structure shown in FIG. 2C is disposed in a carbon-containing atmosphere to introduce carbon into the surface portions of the semiconductor layers 104a-104c (i.e., the native oxide layers 208). In some embodiments, a carbon-containing gas such as C₃H₆ gas is introduced into a reaction chamber where the structure shown in FIG. 2C is disposed. As a result, carbon from the C₃H₆ gas may be introduced into the native oxide layers 208. As a result, the modified layers 233′ are formed, as shown in FIG. 2D. In some embodiments, the atomic concentration of carbon of the modified layer 233′ gradually decreases along a direction from the outer surface of the modified layer 233′ (adjacent to the recess 130) towards the inner surface of the modified layer 233′ (adjacent to the dielectric sacrificial layers 206a-206c or the semiconductor layers 104a-104c).

In some embodiments, the surface portions of the dielectric sacrificial layers 206a-206c and the semiconductor layers 104a-104c (or the native oxide layers 208) are exposed to the carbon-containing gas such as C₃H₆ gas at an elevated temperature. In some embodiments, the native oxide layers 208 are exposed to C₃H₆ gas at a temperature in a range from about 550 degrees C. to about 650 degrees C. for a duration of about 10 minutes to about 2 hours.

Each of the modified layers 233′ has multiple portions including first portions P1′ near the dielectric sacrificial layers 206a-206c and second portions P2′ near the semiconductor layers 104a-104c. In some embodiments, the compositions of the first portions P1′ and the second portions P2′ are different. In some embodiments, the dielectric sacrificial layers 206a-206c are made of silicon oxide. The first portions P1′ may be made of carbon-containing silicon oxide. The atomic concentration of carbon of the first portions P1′ may be in a range from about 1% to about 15%. In some embodiments, the semiconductor layers 104a-104c are made of silicon. The second portions P2 may be made of carbon-containing silicon oxide. In some embodiments, the atomic concentration of silicon of the second portion P2′ is higher than that of the first portion P1′.

In some embodiments, the modifying elements include boron. The structure shown in FIG. 2C is disposed in a boron-containing atmosphere to introduce boron into the native oxide layers 208. In some embodiments, a boron-containing plasma is introduced into a reaction chamber where the structure shown in FIG. 2C is disposed. As a result, boron from the boron-containing plasma may be introduced into the native oxide layers 208 and the dielectric sacrificial layers 206a-206c. In some embodiments, an ion implantation process is used to introduce boron. As a result, the modified layers 233′ are formed, as shown in FIG. 2D. In some embodiments, the atomic concentration of boron of the modified layer 233′ gradually decreases along a direction from the outer surface of the modified layer 233′ (adjacent to the recess 130) towards the inner surface of the modified layer 233′ (adjacent to the dielectric sacrificial layers 206a-206c or the semiconductor layers 104a-104c).

Each of the modified layers 233′ has multiple portions including first portions P1′ near the dielectric sacrificial layers 206a-206c and second portions P2′ near the semiconductor layers 104a-104c. In some embodiments, the compositions of the first portions P1′ and the second portions P2′ are different. In some embodiments, the dielectric sacrificial layers 206a-206c are made of silicon oxide. The first portions P1′ may be made of boron-containing silicon oxide. The atomic concentration of boron of the first portions P1′ may be in a range from about 0.5% to about 1%. In some embodiments, the semiconductor layers 104a-104c are made of silicon. The second portions P2 may be made of boron-containing silicon oxide. In some embodiments, the atomic concentration of silicon of the second portion P2′ is higher than that of the first portion P1′.

Many variations and/or modifications can be made to embodiments of the disclosure. In some other embodiments, two or more kinds of modifying elements are introduced into the surface portions of the dielectric sacrificial layers 206a-206c and the semiconductor layers 104a-104c. As a result, the obtained modified layers may contain two or more kinds of modifying elements. The etching resistance of the modified layers may be improved.

As shown in FIG. 2E, an insulating layer 134 is deposited, in accordance with some embodiments. The material and formation method of the insulating layer 134 may be the same as or similar to those of the insulating layer 134 shown in FIG. 1E.

As shown in FIG. 2F, similar to the embodiments illustrated in FIG. 1F, the insulating layer 134 and the modified layers 233′ are partially removed, in accordance with some embodiments. As a result, the remaining portions of the modified layers 233′ form multiple protective elements (or modified elements) 233″, and the remaining portions of the insulating layer 134 form multiple inner spacers 136.

As shown in FIG. 2F, each of the protective elements 233″ has a first portion P1″ and a second portion P2″. The first portion P1″ is adjacent to one of the dielectric sacrificial layers 206a-206c, and the second portion P2″ is adjacent to the semiconductor layers 104a-104c nearby. The first portion P1″ of the protective element 233″ may be made of or include nitrogen-containing silicon oxide, carbon-containing silicon oxide, boron-containing silicon oxide, another suitable material, or a combination thereof. The second portion P2″ of the protective element 233″ may be made of or include nitrogen-containing silicon oxide, carbon-containing silicon oxide, boron-containing silicon oxide, another suitable material, or a combination thereof. In some embodiments, the second portion P2″ of the protective element 233″ has a higher atomic concentration of silicon than that of the first portion P1″.

As shown in FIG. 2G, epitaxial structures 138 and a dielectric layer 140 are sequentially formed, in accordance with some embodiments. The material and formation method of the epitaxial structures 138 may be the same as or similar to those of the epitaxial structures 138 illustrated in FIG. 1G. The material and formation method of the dielectric layer 140 may be the same as or similar to those of the epitaxial structures 138 illustrated in FIG. 1G.

As shown in FIG. 2H, similar to the embodiments illustrated in FIG. 1H, the dummy gate stacks 120A and 120B are removed to form multiple trenches 142, in accordance with some embodiments. Similar to the removal of the semiconductor layers 102a-102c, the dielectric sacrificial layers 206a-206c are also removed to form multiple recesses 144. The semiconductor layers 104a-104c are thus released. The remaining portions of the semiconductor layers 104a-104c form multiple semiconductor nanostructures 104a′-104c′, as shown in FIG. 2H. The protective elements 233″ and the inner spacers 136 work together to prevent the epitaxial structures 138 from being damaged during the removal of the dielectric sacrificial layers 206a-206c.

As shown in FIG. 2I, similar to the embodiments illustrated in FIG. 1I, multiple metal gate stack layers are formed to fill the trenches 142 and the recesses 144, in accordance with some embodiments. As a result, the semiconductor nanostructures 104a′-104c′ are surrounded by the metal gate stack layers. Similar to the embodiments shown in FIG. 1I, the metal gate stack layers include a gate dielectric layer 150, a work function layer 152, and a conductive filling layer 154. The material and formation method of the gate dielectric layer 150 may be the same as or similar to those of the gate dielectric layer 150 shown in FIG. 1I. The material and formation method of the work function layer 152 may be the same as or similar to those of the work function layer 152 shown in FIG. 1I. The material and formation method of the conductive filling layer 154 may be the same as or similar to those of the conductive filling layer 154 shown in FIG. 1I.

FIG. 2J-1 is a top view of an intermediate stage of a process for forming a portion of a semiconductor device structure, in accordance with some embodiments. In some embodiments, FIG. 2J is a cross-sectional view of the structure taken along the line I-I′ in FIG. 2J-1. FIG. 2J-2 is a cross-sectional view of an intermediate stage of a process for forming a portion of a semiconductor device structure, in accordance with some embodiments. In some embodiments, FIG. 2J-2 is a cross-sectional view of the structure taken along the line II-II′ in FIG. 2J-1. FIG. 2J-3 is a cross-sectional view of an intermediate stage of a process for forming a portion of a semiconductor device structure, in accordance with some embodiments. In some embodiments, FIG. 2J-3 is a cross-sectional view of the structure taken along the line III-III′ in FIG. 2J-1.

As shown in FIGS. 2J, 2J-1, 2J-2, and 2J-3, similar to the embodiments illustrated in FIGS. 1J, 1J-1, 1J-2, and 1J-3, the metal gate stack layers are partially removed, in accordance with some embodiments. As a result, the remaining portions of the metal gate stack layers form multiple metal gate stacks 156A and 156B.

As shown in FIG. 2J, each of the protective element 233″ has a first surface S1 next to the metal gate stack 156A or 156B and a second surface S2 next to the respective inner spacer 136. In some embodiments, the atomic concentration of the modifying element (such as nitrogen, carbon, and/or boron) at the second surface S2 is higher than that at the first surface S1. In some embodiments, the atomic concentration of the modifying element (such as nitrogen, carbon, and/or boron) gradually increases along a direction from the first surface S1 towards the second surface S2.

In some embodiments, the semiconductor layers 102a-102c are replaced with the dielectric sacrificial layers 206a-206c before the formation of the epitaxial structures that may involve high temperature operations. Therefore, atoms such as germanium from the semiconductor layers 102a-102c are prevented from diffusing into the semiconductor layers 104a-104c during the formation of the epitaxial structures 138. The obtained semiconductor nanostructures 104a′-104c′ may thus have the desired profiles and better surface conditions. The quality and reliability of the semiconductor layers 104a-104c are ensured.

Embodiments of the disclosure modify the surface portions of semiconductor layers and sacrificial layers to turn the native oxide portions into protective elements that have better etching resistance before the formation of the inner spacers. The protective elements and the inner spacers may thus work together to protect the epitaxial structures during the removal of the sacrificial layers. Short circuiting between the metal gate stack and the epitaxial structures is significantly reduced or prevented. The performance and reliability of the semiconductor device structure are greatly improved.

In accordance with some embodiments, a method for forming a semiconductor device structure is provided. The method includes forming multiple sacrificial layers and multiple semiconductor layers laid out in an alternating manner on a substrate. The method also includes partially removing the semiconductor layers and the sacrificial layers to form a first recess exposing side edges of the semiconductor layers and the sacrificial layers and partially removing the sacrificial layers from the side edges of the sacrificial layers to form multiple second recesses. The method further includes introducing modifying elements into the sacrificial layers and the semiconductor layers to transform surface portions of the sacrificial layers and the semiconductor layers into a modified layer. The modifying elements includes nitrogen, carbon, boron, or a combination thereof. In addition, the method includes forming an inner spacer layer over the modified layer and removing the inner spacer layer and the modified layer outside of the second recesses. Remaining portions of the inner spacer layer and the modified layer form inner spacers and modified elements, respectively.

In accordance with some embodiments, a method for forming a semiconductor device structure is provided. The method includes forming fin structure having multiple sacrificial layers and multiple semiconductor layers laid out in an alternating manner on a substrate and forming a dummy gate stack extending across the fin structure. The method also includes partially removing the semiconductor layers and the sacrificial layers to form a first recess exposing side edges of the semiconductor layers and the sacrificial layers and replacing the sacrificial layers with dielectric sacrificial layers. The method further includes partially removing the dielectric sacrificial layers from side edges of the dielectric sacrificial layers to form a plurality of second recesses and modifying surface portions of the dielectric sacrificial layers with modifying elements to transform the surface portions into modified elements. The modifying elements includes nitrogen, carbon, boron, or a combination thereof. In addition, the method includes forming inner spacers covering the modified elements in the second recesses and removing the dummy gate stack and the dielectric sacrificial layers to release a plurality of semiconductor nanostructures constructed by remaining portions of the semiconductor layers after the epitaxial structure is formed. The method also includes forming a metal gate stack wrapped around the semiconductor nanostructures.

In accordance with some embodiments, a semiconductor device structure is provided. The semiconductor device structure includes multiple semiconductor nanostructures and a gate stack wrapped around the semiconductor nanostructures. The semiconductor device structure also includes an epitaxial structure connecting the semiconductor nanostructures and multiple inner spacers between the epitaxial structure and the gate stack. The semiconductor device structure further includes multiple protective elements, and each of the protective elements is positioned between the gate stack and a respective inner spacer of the inner spacers. The protective elements contain nitrogen, carbon, boron, or a combination thereof.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor device structure, comprising:
forming a plurality of sacrificial layers and a plurality of semiconductor layers laid out in an alternating manner on a substrate;
partially removing the semiconductor layers and the sacrificial layers to form a first recess exposing side edges of the semiconductor layers and the sacrificial layers;
partially removing the sacrificial layers from the side edges of the sacrificial layers to form a plurality of second recesses;
introducing modifying elements into the sacrificial layers and the semiconductor layers to transform surface portions of the sacrificial layers and the semiconductor layers into a modified layer, wherein the modifying elements comprises nitrogen, carbon, boron, or a combination thereof;
forming an inner spacer layer over the modified layer; and
removing the inner spacer layer and the modified layer outside of the second recesses, wherein remaining portions of the inner spacer layer and the modified layer form inner spacers and modified elements, respectively.

2. The method of claim 1, wherein the sacrificial layers comprise silicon germanium.

3. The method of claim 2, wherein the surface portions of the sacrificial layers comprise silicon-germanium oxide, and the surface portions of the semiconductor layers comprises silicon oxide.

4. The method of claim 1, wherein the sacrificial layers are made of an oxide material.

5. The method of claim 1, further comprising:
forming an epitaxial structure in the first recess to cover the side edges of the semiconductor layers, the inner spacers, and the modified elements;
removing the sacrificial layers to release a plurality of semiconductor nanostructures constructed by remaining portions of the semiconductor layers after the epitaxial structure is formed; and
forming a metal gate stack wrapped around the semiconductor nanostructures.

6. The method of claim 1, wherein the modifying elements are introduced into the sacrificial layers and the semiconductor layers by exposing the surface portions of the sacrificial layers and the semiconductor layers to a nitrogen-containing atmosphere, a carbon-containing atmosphere, a boron-containing atmosphere, or a combination thereof.

7. The method of claim 6, wherein the modifying elements comprise nitrogen, and the modifying elements are introduced into the sacrificial layers and the semiconductor layers by exposing the surface portions of the sacrificial layers and the semiconductor layers to NH₃ gas at a temperature in a range from about 550 degrees C. to about 600 degrees C. for a duration of about 10 minutes to about 2 hours.

8. The method of claim 1, wherein the modifying elements comprise carbon, and the modifying elements are introduced into the sacrificial layers and the semiconductor layers by exposing the surface portions of the sacrificial layers and the semiconductor layers to C₃H₆ gas at a temperature in a range from about 550 degrees C. to about 650 degrees C. for a duration of about 10 minutes to about 2 hours.

9. The method of claim 1, wherein the modifying elements comprise boron, and the modifying elements are introduced into the sacrificial layers and the semiconductor layers by exposing the surface portions of the sacrificial layers and the semiconductor layers to boron-containing plasma.

10. The method of claim 1, wherein each of the modified elements is formed to have a thickness in a range from about 3 angstroms to about 15 angstroms.

11. A method for forming a semiconductor device structure, comprising:
forming fin structure having a plurality of sacrificial layers and a plurality of semiconductor layers laid out in an alternating manner on a substrate;
forming a dummy gate stack extending across the fin structure;
partially removing the semiconductor layers and the sacrificial layers to form a first recess exposing side edges of the semiconductor layers and the sacrificial layers;
replacing the sacrificial layers with dielectric sacrificial layers;
partially removing the dielectric sacrificial layers from side edges of the dielectric sacrificial layers to form a plurality of second recesses;
modifying surface portions of the dielectric sacrificial layers with modifying elements to transform the surface portions into modified elements, wherein the modifying elements comprises nitrogen, carbon, boron, or a combination thereof;
forming inner spacers covering the modified elements in the second recesses;
removing the dummy gate stack and the dielectric sacrificial layers to release a plurality of semiconductor nanostructures constructed by remaining portions of the semiconductor layers; and
forming a metal gate stack wrapped around the semiconductor nanostructures.

12. The method of claim 11, wherein the modifying elements comprise nitrogen, and the modifying elements are introduced into the dielectric sacrificial layers and the semiconductor layers by exposing the surface portions of the dielectric sacrificial layers and the semiconductor layers to NH₃ gas at a temperature in a range from about 550 degrees C. to about 600 degrees C. for a duration of about 10 minutes to about 2 hours.

13. The method of claim 11, wherein the modifying elements comprise carbon, and the modifying elements are introduced into the dielectric sacrificial layers and the semiconductor layers by exposing the surface portions of the dielectric sacrificial layers and the semiconductor layers to C₃H₆ gas at a temperature in a range from about 550 degrees C. to about 650 degrees C. for a duration of about 10 minutes to about 2 hours.

14. The method of claim 11, wherein the modifying elements comprise boron, and the modifying elements are introduced into the dielectric sacrificial layers and the semiconductor layers by using an ion implantation process.

15. The method of claim 11, further comprising:
forming a source/drain epitaxial structure in the first recess, wherein the source/drain epitaxial structure is formed to be in direct contact with the inner spacers and the modified elements.

16. A semiconductor device, comprising:
a plurality of semiconductor nanostructures;
a gate stack wrapped around the semiconductor nanostructures;
an epitaxial structure connecting the semiconductor nanostructures;
a plurality of inner spacers between the epitaxial structure and the gate stack; and
a plurality of protective elements, wherein each of the protective elements is positioned between the gate stack and a respective inner spacer of the inner spacers, and the protective elements contain nitrogen, carbon, boron, or a combination thereof.

17. The semiconductor device of claim 16, wherein the protective elements comprise nitrogen-containing silicon oxide, nitrogen-containing silicon-germanium oxide, carbon-containing silicon oxide, carbon-containing silicon-germanium oxide, boron-containing silicon oxide, boron-containing silicon-germanium oxide, or a combination thereof.

18. The semiconductor device of claim 16, wherein the inner spacers have an atomic concentration of an element higher than that of the protective elements, and the element comprises nitrogen, carbon, boron, or a combination thereof.

19. The semiconductor device of claim 16, wherein the epitaxial structure is in direct contact with the inner spacers and the protective elements.

20. The semiconductor device of claim 16, wherein the inner spacers are separated from the semiconductor nanostructures by the protective elements.
